(19) United States
(12) Patent Application Publication
(10) Pub. No.: US 2012/0105064 A1
(43) Pub. Date: May 3, 2012

(54) RADIO FREQUENCY COIL FOR MAGNETIC RESONANCE IMAGING SYSTEM

(76) Inventors: Santosh Kumar, Bangalore (IN); Prasidh Ramabadran, Bangalore (IN); Sharachhandra Rao, Bangalore (IN)

(21) Appl. No.: 13/286,483

(22) Filed: Nov. 1, 2011

(30) Foreign Application Priority Data
Nov. 1, 2010 (IN) 3239/CHE/2010

(51) Int. Cl. G01R 33/44

(52) U.S. Cl. 324/322

(57) ABSTRACT

In one embodiment a radio frequency receiver for a magnetic resonance imaging system is provided. The radio frequency receiver comprises a RF coil for receiving one or more radio frequency signals transmitted through an object to be imaged so as to enable a reconstruction processor to generate an image representation of the object based on the received radio frequency signals, a local oscillator configured for generating a stimulus, the stimulus comprising a range of radio frequency signals having different frequencies and a flux probe coupled to the local oscillator, the flux probe configured for applying the stimulus to the RF coil. Further, the RF coil is configured for returning a reflected signal in response to the stimulus applied and comprises at least one digitally tunable capacitor.

### FIELD OF THE INVENTION

The invention generally relates to a magnetic resonance imaging system and more particularly to RF coils used in the magnetic resonance imaging systems.

### BACKGROUND OF THE INVENTION

The radio frequency (RF) field that is intended to be sensed by an RF coil in a magnetic resonance imaging (MRI) system is of near nature i.e. the distance between the RF transmitter and the RF receiver is less than the wavelength of the signal that is to be sensed. The MRI system comprises an opening referred to herein as bore that receives the object that is to be imaged. Further, the MRI system comprises an RF shield around the bore, which influences the resonant frequency of the RF coil depending on the diameter of the bore and the distance of the RF coil from the center of the bore. For example, an RF coil tuned for a resonant frequency of A MHz in a bore having a diameter of 60 cm exhibits a resonant frequency of B MHz in a bore having a diameter of 70 cm due to variation in the distance between the RF coil and the RF shield.

The RF coil comprises an inductive element and a capacitive element. The value of the inductive element is fixed and therefore in order to achieve tunability, the capacitive elements in the RF coil comprise combinations of fixed and mechanically variable capacitors.

Conventionally, the RF coils are tuned in an iterative manner, initially without load, then with load, and then in an RF shield simulator, by manually adjusting one or more tuning knobs of the variable capacitor.

Further, one of the prior arts achieves tunability by incorporating movable end rings. Another prior art uses a frequency synthesizer to apply the stimulus. A microcontroller tunes a varactor diode in accordance with the frequency response. This is a proven technique with experimental demonstration of SNR improvement. However, one of the limitations associated with this technique is the system uses an external signal source and the tuning is performed by an external equipment. Further the varactor diode is more susceptible to noise and has lower temperature stability.

Hence there exists a need for a magnetic resonance imaging system that achieves tunability by self, which is also automatic, efficient and reliable.

### BRIEF DESCRIPTION OF THE INVENTION

The above-mentioned shortcomings, disadvantages and problems are addressed herein which will be understood by reading and understanding the following specification.

In one embodiment a radio frequency receiver for a magnetic resonance imaging system is provided. The radio frequency receiver comprises a RF coil for receiving one or more radio frequency signals transmitted through an object to be imaged so as to enable a reconstruction processor to generate an image representation of the object based on the received radio frequency signals, a local oscillator configured for generating a stimulus, the stimulus comprising a range of radio frequency signals having different frequencies and a flux probe coupled to the local oscillator, the flux probe configured for applying the stimulus to the RF coil. Further, the RF coil is configured for returning a reflected signal in response to the stimulus applied and comprises at least one digitally tunable capacitor.

In another embodiment a magnetic resonance imaging (MRI) system is provided. The magnetic resonance imaging system comprises a radio frequency transmitter for transmitting a range of radio frequency signals through an object to be imaged, a radio frequency receiver for receiving the radio frequency signals transmitted through the object and a reconstruction processor for reconstructing an image representation of the object from the signals received by the radio frequency receiver to display on a human viewable display. Further, the radio frequency receiver comprises a RF coil comprising at least one digitally tunable capacitor.

In yet another embodiment, a method of calibrating and operating a magnetic resonance imaging system comprising a RF coil is provided. The method comprises steps of performing a calibration scan to determine a resonant frequency of the RF coil, the resonant frequency being different from the larmor frequency of the RF coil and wherein the RF coil comprises at least one fixed capacitor and at least one digitally tunable capacitor. Obtaining value of the at least one fixed capacitor from a coil configuration file, reading tuned value of the digitally tunable capacitor from a digital serial configuration word, the tuned value of the digitally tunable capacitor corresponding to the resonant frequency of the RF coil, calculating a desired value for the digitally tunable capacitor based on the value of the fixed capacitors and the tuned value of the digitally tunable capacitor, the desired value of the digitally tunable capacitor being the value of the digitally tunable capacitor corresponding to the larmor frequency and programming the desired value into the digitally tunable capacitor.

Systems and methods of varying scope are described herein. In addition to the aspects and advantages described in this summary, further aspects and advantages will become apparent by reference to the drawings and with reference to the detailed description that follows.

### BRIEF DESCRIPTION OF THE DRAWINGS

FIG. 1 shows a block diagram of a magnetic resonance imaging system, as described in an embodiment of the invention; and

FIG. 2 shows a method of calibrating and operating the magnetic resonance imaging system shown in FIG. 1.

### DETAILED DESCRIPTION OF THE INVENTION

In the following detailed description, reference is made to the accompanying drawings that form a part hereof, and in which is shown by way of illustration specific embodiments, which may be practiced. These embodiments are described in sufficient detail to enable those skilled in the art to practice the embodiments, and it is to be understood that other embodiments may be utilized and that logical, mechanical, electrical and other changes may be made without departing from the scope of the embodiments. The following detailed description is, therefore, not to be taken in a limiting sense.

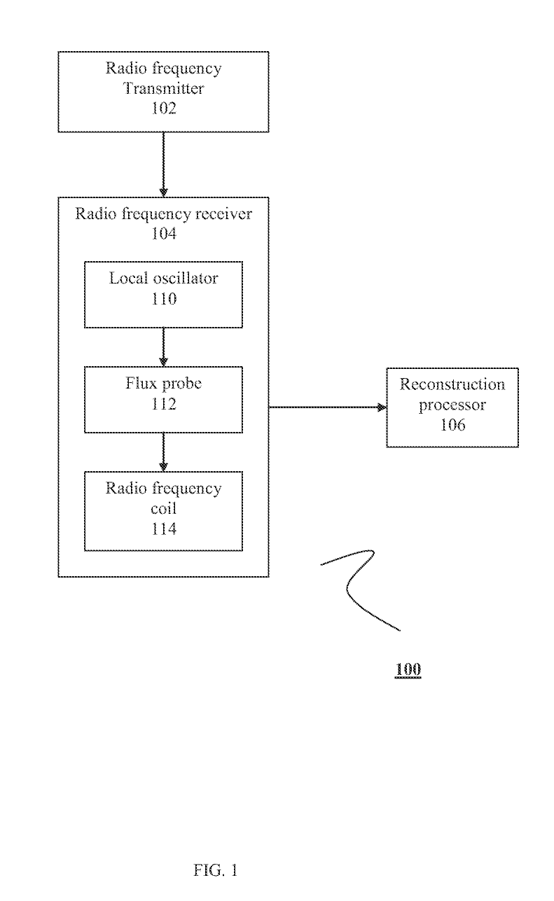

In one embodiment, as shown in FIG. 1, a magnetic resonance imaging (MRI) system is provided. The magnetic resonance imaging system comprises a radio frequency transmitter 102 for transmitting a range of radio frequency signals through an object to be imaged, a radio frequency receiver 104 for receiving the radio frequency signals transmitted through the object and a reconstruction processor 106 for reconstructing an image representation of the object from the signals received by the radio frequency receiver 104 to display on a human viewable display.

The radio frequency receiver 104 in the MRI system comprises an RF coil 114 for receiving one or more radio frequency signals transmitted through the object to be imaged so as to enable the reconstruction processor 106 to generate an image representation of the object based on the received radio frequency signals.

A typical MRI system includes a bore for receiving the object to be imaged, a main magnet for applying a static magnetic field to the object to be imaged, and three gradient magnets for applying a gradient field in each of three Cartesian coordinates, x, y, and z, respectively. The MRI system further comprises associated hardware and software for applying and pulsing magnetic and RF fields, in a manner known to those of skill in the art. During an imaging scan, the RF coil 114 is coupled around the object to be imaged. The object and associated RF coil 114 are subjected to a static magnetic field supplied by the main magnet, which causes alignment of nuclear spins of the atomic nuclei of hydrogen atoms in the object. The RF coil 114 is pulsed at a resonant frequency to provide RF excitation pulses to the object which effect precessional motion of the atomic nuclei at the characteristic Larmor frequency.

Typically, as noted above, the RF coil 114 of the radio frequency receiver 104 in the MRI system is tuned to the larmor frequency depending on the field strength of the magnet involved in the RF receiver 104. The RF coil 114 is required to exhibit high selectivity and minimum reflection at the Larmor frequency. However, the presence of an RF shield around the bore influences the resonant frequency of the RF coil 114 depending on the diameter of the bore and the distance of the RF coil 114 from the center of the bore.

The RF coil 114 is a resonant circuit comprising at least one inductive element and at least one capacitive element in series with the inductive element. The value of the inductive and the capacitive elements in the RF coil 114 determine the resonant frequency of the RF coil 114. Therefore, the resonant frequency of the RF coil 114 can be varied, in order to tune the RF coil 114 to the larmor frequency, by varying at least one of the values of the inductive and the capacitive element that form the RF coil 114. With the advent of microelectronics, realization of digital control for parameters has been possible. The invention provides an RF coil 114 whose resonant frequency is tunable digitally while being connected to the RF receiver 104, making it independent of bore diameter.

The inductive element is formed by a conductor and the inductance is determined by the length and width of the conductor forming the inductive element. The inductance of the inductive element therefore is typically constant. In order to achieve tunability, the capacitive elements in the RF coil 114 comprise combinations of fixed and variable capacitors. Accordingly, the capacitive element of the RF coil 114 comprises at least one fixed capacitor and at least one variable capacitor i.e., digitally tunable capacitor. Tunability of the RF coil 114 is achieved by varying the capacitance of the variable capacitor.

At any time, the frequency at which the RF coil 114 is tuned is determined by performing a calibration scan. For this purpose, the radio frequency receiver 104 comprises a local oscillator 110 configured for generating a stimulus, the stimulus comprising a range of radio frequency signals having different frequencies and a flux probe 112 coupled to the local oscillator 110. The flux probe 112 is configured for applying the stimulus to the RF coil 114. Further, the RF coil 114 is configured for receiving the stimulus and for returning a reflected signal in response to the received stimulus.

The method of performing the calibration scan comprises fixing the flux probe 112 at the center of the bore, generating a stimulus using the local oscillator 110, applying the stimulus through the flux probe 112 to the RF coil 114, receiving a reflected signal from the RF coil 114 and analyzing the reflected signal to identify the resonant frequency. The resonant frequency is the frequency at which energy transfer into the RF coil 114 is maximized. Further, the maximum energy transfer into the RF coil 114 is determined by the maximum amplitude of the reflected signal received from the RF coil 114.

The value of the fixed capacitors is obtained from a coil configuration file. The coil configuration file for a given RF coil 114 may contain the value of the total loop inductance, fixed capacitance and the capacitance control information. The RF receiver 104 may perform a probing scan or a calibration scan with a wide RF bandwidth on a standard phantom to determine the peak in the spectrum. The peak in the spectrum represents the resonant frequency of the RF coil 114. In other words, peak in the spectrum represents the frequency at which the RF coil 114 is tuned. The peak may appear at a frequency above or below the Larmor frequency depending on the offset caused by the bore diameter. In order to tune the RF coil 114 to the Larmor frequency, the capacitance needs to be increased or decreased proportional to the difference in the actually tuned frequency and the Larmor frequency.

In an exemplary embodiment, the RF coil 114 is tuned to a resonant frequency ‘fa’ which is slightly above the Larmor frequency ‘fc’. Let ‘L” be the value of the inductive element in the RF coil 114. The resonant frequency fa is equal to 1/(2*pi*sqrt(L*Ca)) where Cu is the value of the capacitive element in the RF coil 114 at the resonant frequency ‘fa’. The Larmor frequency fc is equal to 1/(2*pi*sqrt(L*Cc)) where Cc is the value of the capacitive element in the RF coil 114 at the Larmor Frequency ‘fc’.

The values of the fixed capacitors are obtained from the coil configuration file. The tuned value of the digitally tunable capacitor is read through a digital serial configuration word. The value of the capacitive element “Ca” is equal to the series combination of the fixed capacitor and the tuned value of the digitally tunable capacitor.

The desired value for the digitally tunable capacitor may be calculated based on the value of the fixed capacitors and the tuned value of the digitally tunable capacitor. The desired value is programmed into the digitally tunable capacitor using a digital programming interface. The digital programming interface is a three wire serial interface that uses a communication protocol depending on the compatibility of the memory device. The communication protocol is one of inter IC bus and Serial Peripheral Interface bus. Skilled artisans shall however appreciate the use of other compatible communication protocols. This desired value programmed into the digitally tunable capacitor may tune the RF coil 114 to the Larmor frequency.

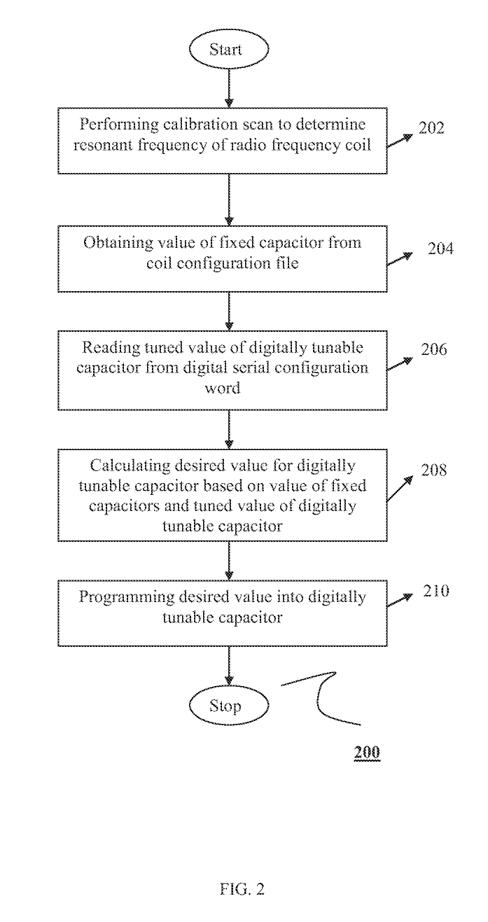

Accordingly, in another embodiment, as shown in FIG. 2, a method 200 of calibrating and operating the magnetic resonance imaging system is provided. The method 200 comprises steps of performing a calibration scan to determine a resonant frequency of the RF coil 114 at step 202, obtaining value of the at least one fixed capacitor from the coil configuration file at step 204, reading tuned value of the digitally tunable capacitor from the digital serial configuration word at step 206, calculating a desired value for the digitally tunable capacitor based on the value of the fixed capacitors and the tuned value of the digitally tunable capacitor at step 208, and programming the desired value into the digitally tunable capacitor at step 210.

As noted above, the resonant frequency of the RF coil 114 is determined by the value of the inductive element and the capacitive element that form the sensing loop. As the value of the inductive element is fixed, the RF coil 114 can be tuned by varying the value of the capacitive element. The capacitive element of the RF coil 114 comprises at least one fixed capacitor and at least one variable capacitor. The variable capacitor comprises a digitally tunable capacitor and a memory device such as an Electrically Programmable Read Only Memory (EPROM). The digitally tunable capacitor is coupled to the memory device and can be tuned by sending a digital serial configuration word from the RF receiver 104.

In an alternative embodiment, the RF transmitter 102 may comprise an RF generator that generates a range of RF signals having different frequencies. The output of the RF generator may be coupled (prior to power amplification) to the flux probe 112 that can be fixed at the center of the bore by means of a cardboard fixture. The flux probe 112 may then apply the stimulus to the RF coil 114. The stimulus may subsequently be reflected by the RF coil 114. The frequency of the RF generator is swept over a range and the amplitude of the RF signal reflected from the RF coil 114 is detected and stored. The frequency of the RF signal at which the amplitude of the reflected signal from the RF coil 114 is maximum implies the frequency “fa” at which the RF coil 114 is tuned. This information may be used to tune the RF coil 114 to the desired resonant frequency “fc” from the knowledge of “fa”, inductance “L” and fixed capacitance “Cf” as explained above.

The method of calibrating the MRI system 100 described herein uses the local oscillator 110 in the RF receiver 104 to apply the stimulus and does not require an external signal source. The stimulus is applied through the flux probe 112. There is no need to tap the RF coil 114 at the RF port prior to the pre-amp as is done in the prior art. The tunable element is digital unlike the vat-actor diode used in the prior art that is more susceptible to noise and has lower temperature stability.

Some of the advantages of the RF coil 114 provided in various embodiments of the invention include, elimination of an external test and measurement equipment for tuning the RF coil 114 as the tuning is performed by the RF receiver 104 itself, eliminating the need for an expensive network analyzer and its periodic calibration activity, elimination of repetitive and/or iterative manual tuning process in various bore conditions, digital tuning performed on the basis of capacitance calculated from probe scan or real time spectrum analysis, a single digital tuning cycle to be performed, reduction in tuning time, increased accuracy in tuning, compatibility over various bore sizes with the same field strength, robust architecture, high reliability, repeatability and ease of production and compatibility with digital Automatic Test Equipment (ATE) for mass production and mass testing with the features of DFM (Design for manufacturability) and DPI (Design for Testability) as the tuning elements retain the tuning data and are more suitable for multi channel RF coils.

In addition, the RF coil described herein has no considerable impact on cost, as the only additional hardware that is to be sourced is digital capacitor in the RF coil with a data controller. These are generally of low cost.

In various embodiments of the invention, a RF coil for a magnetic resonance imaging system and a magnetic resonance imaging system using a RF coil are described. However, the embodiments are not limited and may be implemented in connection with different applications. The application of the invention can be extended to other areas, for example imaging systems. The design can be carried further and implemented in various forms and specifications.

This written description uses examples to describe the subject matter herein, including the best mode, and also to enable any person skilled in the art to make and use the subject matter. The patentable scope of the subject matter is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A radio frequency receiver for a magnetic resonance imaging system, the radio frequency receiver comprising:
a RF coil for receiving one or more radio frequency signals transmitted through an object to be imaged so as to enable a reconstruction processor to generate an image representation of the object based on the received radio frequency signals;
a local oscillator configured for generating a stimulus, the stimulus comprising a range of radio frequency signals having different frequencies; and
a flux probe coupled to the local oscillator, the flux probe configured for applying the stimulus to the RF coil;
wherein the RF coil is configured for receiving the stimulus and for returning a reflected signal in response to the received stimulus and comprises at least one digitally tunable capacitor.

2. The radio frequency receiver of claim 1, wherein the capacitive element comprises a memory device and the digitally tunable capacitor is coupled to the memory device.

3. A magnetic resonance imaging (MRI) system comprising:
a radio frequency transmitter for transmitting a range of radio frequency signals through an object to be imaged;
a radio frequency receiver for receiving the radio frequency signals transmitted through the object; and
a reconstruction processor for reconstructing an image representation of the object from the signals received by the radio frequency receiver to display on a human viewable display;
wherein the radio frequency receiver comprises a RF coil comprising at least one digitally tunable capacitor.

4. A method of calibrating and operating a magnetic resonance imaging system comprising a RF coil, the method comprising:
performing a calibration scan to determine a resonant frequency of the RF coil, the resonant frequency being different from the larmor frequency of the RF coil and wherein the RF coil comprises at least one fixed capacitor and at least one digitally tunable capacitor;
obtaining value of the at least one fixed capacitor from a coil configuration file;
reading tuned value of the digitally tunable capacitor from a digital serial configuration word, the tuned value of the digitally tunable capacitor corresponding to the resonant frequency of the RF coil;
calculating a desired value for the digitally tunable capacitor based on the value of the fixed capacitors and the tuned value of the digitally tunable capacitor, the desired value of the digitally tunable capacitor being the value of the digitally tunable capacitor corresponding to the larmor frequency; and
programming the desired value into the digitally tunable capacitor.

5. The method of claim 4, wherein the digital serial configuration word is stored in a memory device.

6. The method of claim 4, wherein the desired value is programmed into the digitally tunable capacitor using a digital programming interface and wherein the digital programming interface is a three wire serial interface.

7. The method of claim 6, wherein the digital programming interface uses a communication protocol depending on the compatibility of the memory device.

8. The method of claim 7, wherein the communication protocol is one of inter IC bus and Serial Peripheral Interface bus.

9. The method of claim 4, wherein performing the calibration scan comprises:
fixing a flux probe at the center of a bore;
generating a stimulus using a local oscillator, the stimulus comprising a range of radio frequency signals having different frequencies;
applying the stimulus through the flux probe to the RF coil;
receiving a reflected signal from the RF coil, the reflected signal being generated in response to the stimulus applied; and
analyzing the reflected signal to identify the resonant frequency, the resonant frequency being the frequency at which energy transfer into the RF coil is maximized.

10. The method of claim 9, wherein the maximum energy transfer into the RF coil is determined by the maximum amplitude of the reflected signal received from the RF coil.
